(19) United States
(12) Patent Application Publication
(10) Pub. No.: US 2005/0269666 A1
(43) Pub. Date: Dec. 8, 2005

(54) Electrical fuses as programmable data storage

(75) Inventors: Shine Chien Chung, Sanchung City (TW); Chine-Gie Lou, Hsinchu Hsien (TW)

Correspondence Address: DUANE MORRIS, LLP;IP DEPARTMENT, 30 SOUTH 17TH STREET, PHILADELPHIA, PA, 19103-4196, US

(73) Assignee: Taiwan Semiconductor Manufacturing Company, Ltd.

(21) Appl. No.: 11/056,041

(22) Filed: Feb. 11, 2005

Related U.S. Application Data
(60) Provisional application No. 60/577,612, filed on Jun. 7, 2004.

(51) Int. Cl. H01L 29/00

(52) U.S. Cl. 257/528

(57) ABSTRACT

An electrical fuse is disclosed. It is formed by a silicide layer on a polysilicon layer, with a first dielectric section separating the electrical fuse from a semiconductor substrate and a second dielectric section separating the electrical fuse from at least one electrical conductor directly above the fuse. The polysilicon layer is at least 2000 Angstroms in thickness and no more than 0.14 um in width and the second dielectric section contains substantially low-K materials.

### CROSS REFERENCE

This application claims the benefits of U.S. Provisional Patent Application No. 60/577,612 entitled “Electrical Fuses As Programmable Data Storage”, which was filed on Jun. 7, 2004.

### BACKGROUND

The present invention relates generally to device structures, and more particularly to new electrical fuses that can be programmed predictably and used as data storage elements.

Electrical fuses are designed to “blow” when a current through the fuses exceeds a threshold. After a fuse is “blown”, the resistance of the fuse may be redefined. Since the state of a blown fuse is relatively stable, it may provide some form of nonvolatile data storage, in which the data is unchanged after the power is turned off. The applications of using the electrical fuses in standard CMOS compatible processes are many, including chip ID, serial number, security keys, feature selection, memory redundancy, and One-Time-Programmable memory (OTP).

Conventional electrical fuses use polysilicon (a.k.a. poly) as material to program into high resistance state. Poly can be applied with high current so that the fuse element will be broken or ruptured. The programming voltage is very high, around 5-10V, and the current is in the range of 20-30 mA. As processing technologies advances, poly tends to be built with a layer of silicide on top. The silicide layer can significantly reduce the poly sheet resistance from 30-100 ohm to 4-10 ohm. Thus, the parasitic interconnect resistance can be reduced by one order of magnitude so that the chip performance can be improved. The silicided poly can be used as electrical fuses. The programming voltage and current can be reduced greatly for this kind of electrical fuse element because the threshold voltage or current to break or to deplete the silicide is much lower than those for the poly.

A given change in the resistance of a fuse can be defined, by programming or a bit of data. However, achieving a consistent replication of the change in resistance of a fuse has been difficult in production. The appropriate construction of a fuse in an integrated circuit (IC) depends on the thermal properties of the immediately surrounding structures. “Blowing” such a fuse is accomplished by the application of a specified voltage or current for a specified time. A predictable amount of heat energy is generated to cause a designed change in the physical state of the fuse, which results in a designed change in the resistance of the fuse. The physical dimensions of a fuse must be specified to assure that it will generate the necessary amount of heat energy in response to programming. If the heat energy is allowed to escape too quickly, the temperature of the fuse cannot rise sufficiently to cause the desired changes.

Across an IC, fuses will likely appear in a variety of locations and structures. The thermal conductivity environments will, in general, not be consistent. So, different power levels will likely be needed to blow various fuses.

In addition, means to ensure a consistent performance of a heat energy operated device are critical. Relatively superior thermal conductors must be located at some specified minimum distance from the fuse and relatively better insulators of a specified minimum thickness must be located immediately next to the fuse. Only with such care, then, can the performance of the fuse be predictable in every situation in production.

Therefore, desirable in the art of fuse designs are additional designs that make fuse blowing a more consistent procedure and at lower power levels.

### SUMMARY

In view of the foregoing, an electrical fuse is disclosed. It is formed by a silicide layer on a polysilicon layer, with a first dielectric section separating the electrical fuse from a semiconductor substrate and a second dielectric section separating the electrical fuse from at least one electrical conductor directly above the fuse. The polysilicon layer is at least 2000 Angstroms in thickness and no more than 0.14 um in width and the second dielectric section contains substantially low-K materials.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 illustrates a generalized electrical fuse.

FIG. 2 illustrates a cross sectional view specifying the dimensions and properties of a fuse structure in accordance with an embodiment of the present invention.

FIG. 3 illustrates another cross sectional view specifying the dimensions and properties of a fuse structure in accordance with an embodiment of the present invention.

### DESCRIPTION

The present invention provides a design to make fuse blowing a more consistent procedure and at lower power levels.

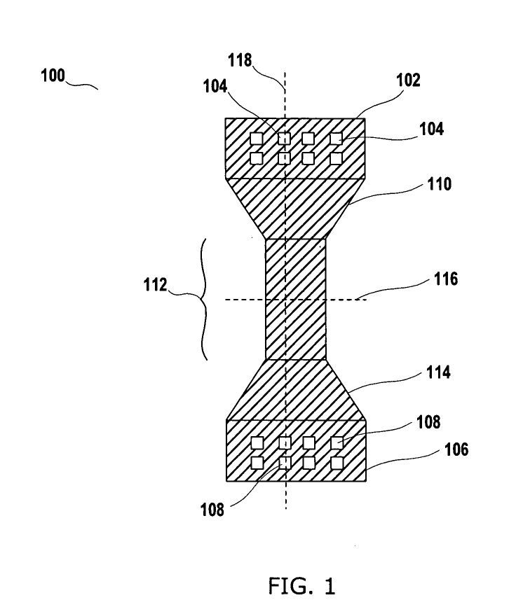

FIG. 1 illustrates a generalized fuse 100 that can be used in a semiconductor integrated circuit (IC). The generalized fuse 100 includes an anode block 102 containing multiple contacts 104 to connect to components of a semiconductor IC, and a cathode block 106 containing multiple contacts 108 as well. There is a taper section 110 that connects the anode block 102 to a neck section 112. The taper section 110 reduces the cross section and increases the resistance of the fuse gradually between the anode block 102 and the neck section 112. A taper section 114 connects the cathode block 106 to the neck section 112. This reduces the cross section and increases the resistance of the fuse gradually between the cathode block 106 and the neck section 112. While constructing the silicided poly fuse, the poly fuse generally contains a layer of poly on top of a dielectric material. Further on top of the poly, a layer of silicide is formed. In order to connect to other circuit elements, two contact areas are placed at two ends of thereof. When the fuse is fabricated initially, a relatively low resistance state is found as the silicide connects between the two ends thereof. When a large current flows through the fuse, it turns into an irreversible high resistance state. It is understood that the fuse structure shown in FIG. 1 is for illustration purpose, and the specific fuse structure may vary.

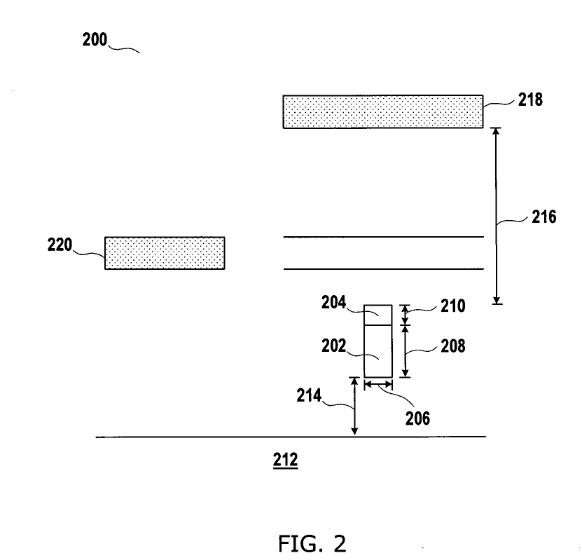

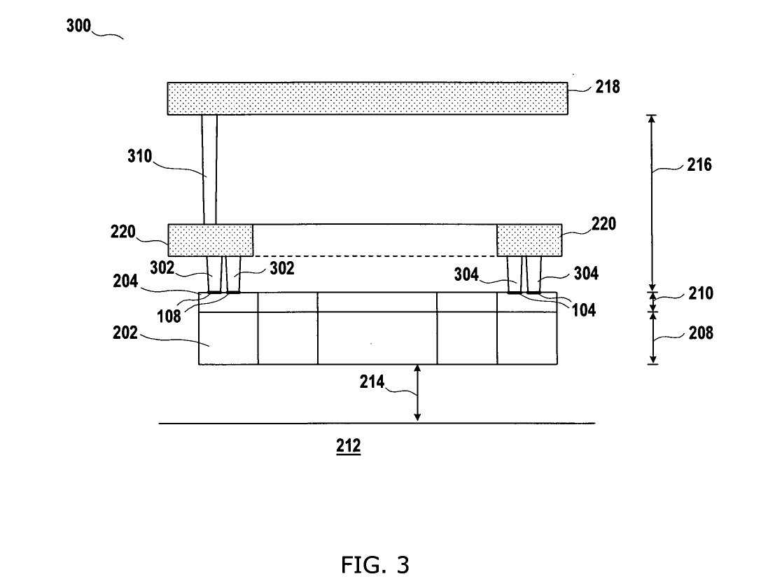

A representative cross sectional view of the fuse structure will be shown in FIG. 2 across a section line 116 in FIG. 1. Another representative cross sectional view of the fuse structure will be shown in FIG. 3 across a section line 118 in FIG. 1. The section line 118 specifically cuts through the neck section 112 and various via contacts at the anode block 102 and the cathode block 106.

FIG. 2 illustrates a cross sectional view 200 specifying the dimensions and properties of a fuse, as well as the thermal properties of its immediately surrounding layer materials in accordance with embodiments of the present invention.

As shown, a fuse in an IC is typically constructed of a polycrystalline silicon (poly) layer 202 with an overcoat of a metal and poly compound (silicide) layer 204. The silicide layer 204 has an electrical resistivity that is much lower than that of the poly layer 202.

Current density is one critical factor in the performance of a fuse. Current density increases inversely with the fuse's cross section, which is the product of its width and thickness. Although the cross section of a fuse should be minimized such that the current density is maximized, the minimum width and thickness of a fuse actually are limited by particular design and semiconductor processing technologies used. The minimum poly width 206 of the poly layer 202 in a fuse pattern is determined by limitations of a photolithography technology. Practically, the poly width 206 is preferably less than 0.14 μm. The poly thickness 208 is preferably less than 2,000 Angstroms. For the fuse function, since the silicide carries most of the fuse current in operation because of its lower resistivity, the thickness of the silicide is also important. For all practical purposes, the silicide thickness 210 is preferably less than 700 Angstroms. Any silicide layer with a thickness over 700 Angstroms may increase the difficulty for “blowing” the fuse. The maximum combined cross section bounded by the maximum poly width 206 and the maximum poly thickness 208 and silicide thickness 210 is preferred to be less than 0.038 um².

A fuse is designed to be programmed or blown under an excessive current flow. It is desirable that the programming occurs at a low power level and that the failure is predictable. The supply voltage in the state-of-art IC technology has been steadily decreased from 5V to 3.3V, 2.5V, 1.8V and then 1.0V. For the 0.13 um technologies and beyond, the supply voltage would stay around 1.0V, and most likely below 1.0 V in the future. This low supply voltage would be hard to program a silicided electrical fuse unless the fuse dimension has been careful designed. Though a relatively high voltage can be used to program electrical fuses, if the high voltage has to last for a long period of time to program the fuses, it may damage the MOS devices. In situation where the fuse is very hard to program, it is even worse. Moreover, the dielectric layers used for isolating different interconnect layers in IC technologies are getting thinner and thinner. The dielectric layers can easily crack if the silicided electrical fuses are very hard to program if excessively high voltage or prohibitive long programming time is required for programming the fuses. Therefore, all these being considered, practical considerations on the dimension of the electrical fuses for programmability are necessary for various fuse designs.

Taking silicided electrical fuses made using 0.13 um semiconductor processing technology and beyond, the fuse dimensions have the following requirements. A first consideration is the cross section of the fuse area. A parameter called Mean-Time-Between-Failure (MTBF) is indicative of how easy the fuse can be programmed. The prediction of the MTBF can be expressed as:
MTBF=KJ⁻ⁿexp(qEₐ/kT)
where, K is a constant, J is the current density, n is a value generally between 1.0 and 5.0, Eₐ is the activation energy, k is Boltzman's constant, and T is the absolute temperature. As indicated by this formula, a higher current density, J, implies a lower, shorter, MTBF. Therefore, a fuse is easier to blow, or program, with a higher current density, J.

Also, a higher temperature implies a lower, shorter, MTBF through the exponential dependence relation of qEₐ/kT. Therefore, a fuse is easier to blow, or program, with a higher temperature. The temperature of the fuse depends primarily on the heat energy delivered to it by the Joule heating generated by the programming current. The quantity of heat is the product of the square of the current and the resistance of the fuse. Of course, some heat is lost, and that slows the heating of the fuse, and therefore, deters the resistance change of the fuse. So, it is necessary to deliver the heat generating current quickly through the fuse and to retain the heat in the fuse during the short time required to complete the resistance change of the fuse. As it is known, heat conducting materials, such as metals, deleteriously remove heat energy. Heat insulating materials, such as dielectrics, allow the heat energy to escape from the fuse relatively slowly. Therefore, a proper design is to wrap a fuse in dielectric layers and to arrange other structures such as metal interconnection wiring at some separated locations.

Referring back to FIG. 2, the poly layer 202 with the silicide layer 204 is typically spaced from a semiconductor substrate 212 by a dielectric section having a total dielectric thickness 214. It is understood that the dielectric section may have a predetermined number of dielectric layers. The dielectric thickness 214 is preferably at least 3,000 Angstroms. Since the dielectric serves as an insulating material, less thickness allows the heat, generated by the operation of blowing the fuse, to be conducted away too quickly. If the heat escapes to the substrate, then the temperature of the fuse cannot rise sufficiently to cause the expected change in the resistance of the fuse.

Similarly, the poly layer 202 with the silicide layer 204 is typically covered by a dielectric section on top thereof having a total dielectric thickness 216. It is understood that the dielectric section has a predetermined number of dielectric layers. The dielectric thickness 216 is preferably at least 3,000 Angstroms. If the heat escapes to the upper structures, such as an interconnection metallization 218, then the temperature of the fuse cannot rise sufficiently to cause the programming to happen in time. Therefore, one immediate adjacent layers of conducting materials such as a level 220 of interconnection metallization should not be designed to run directly above the fuse structure. The interconnection metallization 218 for the fuses is expected to be at least one metal layers removed, or at the second level of metallization from the fuse itself.

In semiconductor devices, different dielectric materials are in use, and different types of dielectric materials may have different thermal conductivities. A different thermal conductivity effectively changes the thickness required to provide a given degree of thermal insulation. In the most recent development, for other purposes having to do with capacitance and circuit speed, low-K dielectrics have been introduced. An undesigned physical property of typical low-K dielectrics is a thermal conductivity that is significantly different from that of the accustomed silicon dioxide. The difference turns out to be an advantage in the construction of a fuse. Typical low-K dielectrics are better insulators than silicon dioxide. Therefore, a fuse can be constructed, with the same quality of resistance change per unit voltage applied during programming, that requires less than the previously specified minimum 3,000 Angstroms in thickness if both low-K dielectric materials are used beneath and above the fuse for thermal insulation. On the other hand, the actual thickness of the dielectric layers is flexible. As long as the minimum is met, having more than the minimum required thickness of dielectric has no significant effect on the performance of the fuse, and the usual design parameters of an IC need not be changed due to the variations of the thickness of the dielectric materials.

While constructing the dielectric materials, a mixture of different types of dielectric layers with different thermal properties, in a stack, is not an unusual situation in an IC. In fact, the mixture actually intends to reduce thermal conductivity with different dielectric materials having different permittivities. It is also advantageous if there are more than two layers of dielectric above the fuse.

A single low-K dielectric layer above a fuse can be thicker than 3,000 Angstromes. If there are two or more low-K dielectric layers, the total thickness is at least 3,000 Angstroms. If there are at least two low-K dielectric layers with a total thickness bigger than 3,000 Angstroms above a fuse, then an additional non-low-K dielectric layer may need to be provided between them to further enhance the thermal isolation and the mechanical strength. According to the present invention, some typical low-K dielectrics such as carbon-doped silicon oxide or fluorine doped silicon oxide can be used for isolating the fuses. Some typical low-K dielectrics have a permittivity less than 3.5 as comparing to 3.9 of silicon dioxide. In another example, a fuse can also be constructed above shallow-trench-isolation (STI), not directly above a substrate. In such a situation, the STI material serves as insulating materials.

With the current processing technology available, the preferred configuration for a fuse can be summarized as such that the width of a poly fuse can be less than 0.14 μm, or even less than 0.11 μm, a total fuse thickness less than 2,700 Angstroms, and a poly thickness less than 2,000 Angstroms. In addition, a total fuse cross sectional area can be less than 0.038 μm². As explained above, clear limiting parameters that govern the construction of a fuse and its immediate surroundings offer predictable performance of the electrical fuses. With the required configuration, the silicided poly electrical fuse can meet the need of low power applications.

FIG. 3 illustrates a cross sectional view 300 specifying the dimensions and properties of the same fuse as illustrated in FIG. 2, as well as the configuration of its immediately surrounding materials in accordance with embodiments of the present invention.

As shown, the fuse is constructed of the poly layer 202 and the silicide layer 204, which has an electrical resistivity that is much lower than that of the poly layer 202. The poly thickness 208 is preferably less than 2,500 Angstroms, and in some situations, less than 2,000 Angstroms. The silicide thickness 210 is preferably less than 700 Angstroms.

As further shown in FIG. 3, the poly layer 202 with the silicide layer 204 is typically spaced from the semiconductor substrate 212 by a dielectric section having the total dielectric thickness 214. It is understood that the dielectric section may have a predetermined number of dielectric layers. The dielectric thickness 214 is preferably at least 3,000 Angstroms. Since the dielectric serves as an insulating material, less thickness allows the heat, generated by the operation of blowing the fuse, to be conducted away too quickly. If the heat escapes to the substrate, then the temperature of the fuse cannot rise sufficiently to cause the expected change in the resistance of the fuse.

Similarly, the poly layer 202 with the silicide layer 204 is typically covered by a dielectric section on top thereof having the total dielectric thickness 216. It is understood that the dielectric section has a predetermined number of dielectric layers. The dielectric thickness 216 is preferably at least 3,000 Angstroms. If the heat escapes to the upper structures, such as the interconnection metallization 218, then the temperature of the fuse cannot rise sufficiently to cause the programming to happen in time. Therefore, one immediate adjacent layers of conducting materials such as the level 220 of interconnection metallization should not be designed to run directly above the fuse structure. The interconnection metallization 218 for the fuses is expected to be at least one metal layers removed, or at the second level of metallization from the fuse itself.

Multiple vias 302 connect a designated portion of the first level 220 of interconnection metallization to multiple contacts 108 of the cathode end of the fuse. Multiple vias 304 connect another portion of the first level 220 of interconnection metallization to multiple contacts 104 of the anode end of the fuse. Finally, a via 310 connects the interconnection metallization 218 to the level 220 of the interconnection metallization, thereby completing the interconnection metallization on top of the fuse. Through multiple vias to connect through multiple layers of interconnection metallization, the electrical fuse is well isolated and not close to any electrical conductor directly above it. Both FIGS. 2 and 3 thus clearly illustrate the configuration of an electrical fuse and its surrounding areas for achieving the best performance.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

1. An electrical fuse comprising:
an electrical fuse formed by a silicide layer on a polysilicon layer;
a first dielectric section separating the electrical fuse from a semiconductor substrate; and
a second dielectric section separating the electrical fuse from at least one electrical conductor directly above the fuse, wherein the polysilicon layer is at least 2000 Angstroms in thickness and no more than 0.14 um in width and the second dielectric section contains substantially low-K materials.

2. The fuse of claim 1, wherein the first dielectric section has a thickness of at least 3,000 Angstroms.

3. The fuse of claim 1, wherein the first dielectric section comprises more than one dielectric material layers.

4. The fuse of claim 1, wherein the second dielectric section has a thickness of at least 3,000 Angstroms.

5. The fuse of claim 1, wherein the electrical conductor is on a layer that is at least one interconnection layer removed from the electrical fuse.

6. The fuse of claim 1, wherein the silicide layer is less than 700 Angstroms in thickness.

7. The fuse of claim 1, wherein a maximum total cross section area of the fuse is less than 0.038 μm.

8. The fuse of claim 1 wherein the electrical fuse is constructed above a trench isolation structure.

9. The fuse of claim 1, wherein the second dielectric section comprises silicon oxide.

10. The fuse of claim 1, wherein the second dielectric section has a permittivity value less than 3.5.

11. The fuse of claim 1, wherein the second dielectric section comprises at least two dielectric layers with at least one low K material.

12. The fuse of claim 11, wherein the dielectric layers with a total thickness of at least 3,000 Angstroms.

13. The fuse of claim 12, wherein an additional dielectric layer is placed between the two low-K dielectric layers if the total thickness is more than 3000 Angstroms.

14. An electrical fuse comprising:
an electrical fuse formed by a silicide layer on a polysilicon layer;
a first dielectric section separating the electrical fuse from a semiconductor substrate; and
a second dielectric section separating the electrical fuse from at least one electrical conductor directly above the fuse,
wherein the silicide layer is no more than 700 Angstroms in thickness and no more than 0.14 um in width and the second dielectric section contains and the second dielectric section contains substantially low-K materials.

15. The fuse of claim 14, wherein the second dielectric section has a thickness of at least 3,000 Angstroms.

16. The fuse of claim 14, wherein the electrical conductor is on a layer that is at least one interconnection layers removed from the electrical fuse.

17. The fuse of claim 14, wherein the second dielectric section comprises at least two dielectric layers with a total thickness of at least 3000 Angstroms.

18. An electrical fuse comprising:
an electrical fuse formed by a silicide layer on a polysilicon layer;
a first dielectric section having a thickness of at least 3,000 Angstroms separating the electrical fuse from a semiconductor substrate; and
a second dielectric section having a thickness of at least 3,000 Angstroms separating the electrical fuse from at least one electrical conductor directly above the fuse,
wherein the silicide layer is no more than 700 Angstroms in thickness and no more than 0.14 um in width and the second dielectric section contains substantially low-K materials.

19. The fuse of claim 18, wherein the electrical conductor is on a layer that is at least one interconnection layer removed from the electrical fuse.

20. The fuse of claim 18, wherein the second dielectric section has a permittivity value less than 3.5.
